(19) United States
(12) Patent Application Publication
(10) Pub. No.: US 2025/0386517 A1
(43) Pub. Date: Dec. 18, 2025

(54) HIGH BANDWIDTH SMALL FORM FACTOR 3D INTEGRATED CIRCUIT PACKAGE INCLUDING MEMORY AND LOGIC

(71) Applicant: QUALCOMM Incorporated, San Diego, CA (US)

(72) Inventors: Jihong CHOI, San Diego, CA (US); Hyun LEE, San Diego, CA (US); Giridhar NALLAPATI, San Diego, CA (US); Mustafa BADAROGLU, San Diego, CA (US); Zhongze WANG, San Diego, CA (US); Woo Tag KANG, San Diego, CA (US); Periannan CHIDAMBARAM, San Diego, CA (US)

(21) Appl. No.: 18/742,390

(22) Filed: Jun. 13, 2024

(51) Int. Cl. H10B 80/00; H01L 21/48; H01L 21/56; H01L 21/768; H01L 23/00; H01L 23/31; H01L 23/538; H01L 25/00; H01L 25/065; H01L 25/18

(52) U.S. Cl. CPC H10B 80/00; H01L 21/4853; H01L 21/4857; H01L 21/565; H01L 21/76898; H01L 23/3128; H01L 23/5383; H01L 23/5386; H01L 23/5389; H01L 24/08; H01L 24/19; H01L 24/20; H01L 24/80; H01L 25/0657; H01L 25/18; H01L 25/50; H01L 2224/08146; H01L 2224/214; H01L 2224/80895; H01L 2224/80896; H01L 2225/06541; H01L 2225/06548; H01L 2924/1431; H01L 2924/1436

(57) ABSTRACT

An integrated circuit package is provided in which a hybrid-bonded stack of memory dies couples through a plurality of through-mold vias to a redistribution layer. A logic die couples to the redistribution layer through a plurality of interconnects.

### TECHNICAL FIELD

The present application relates generally to integrated circuit packaging, and more specifically, to a high bandwidth small form factor three dimensional (3D) integrated circuit package including memory and logic.

### BACKGROUND

The combination of edge computing and artificial intelligence (AI) applications has led to the development of edge AI devices such as sensors in automotive applications, edge-AI-enabled cellular telephones, or Internet of Things (IoT) devices. Prior to the development of edge AI, the engine of an edge computing device (e.g, a microcontroller unit) would typically need to upload data to the cloud for AI processing. But with machine learning built into an edge AI device, the AI processing remains on the device so as to significantly decrease latency, reduce power consumption, and increase data security. In an edge AI device, a data connection from a logic circuit such as the microcontroller unit to its associated memories such as dynamic random-access memories (DRAMs) should have a relatively large bandwidth to accommodate the large amounts of data that travels back and forth from the logic circuit to the memories.

The logic circuit and the DRAMs are typically integrated into separate semiconductor dies. The resulting packaging of the logic die and the DRAM dies into a single integrated circuit package faces significant challenges in maintaining a small form factor and satisfying the relatively large bandwidth needed for the data flow between the logic die and the DRAM dies.

### SUMMARY

In accordance with an aspect of the disclosure, an integrated circuit package is provided that includes: a redistribution layer; a logic die including an active surface coupled to the redistribution layer through a plurality of interconnects; a stack of memory dies stacked from a bottom-most memory die to a top-most memory die, each memory die including an active surface facing the redistribution layer, wherein the active surface of the bottom-most memory die abuts a back side of the logic die, and wherein each memory die, but for the top-most memory die in the stack, includes a plurality of conductive vias extending from the active surface of the memory die to a back side of the memory die; and a plurality of through-mold vias coupled between the active surface of the bottom-most memory die and the redistribution layer.

In accordance with another aspect of the disclosure, a method of manufacturing an integrated circuit package is provided that includes: forming a plurality of through-mold vias on an active surface of a first memory die wafer; securing a back side of a logic die to the active surface of the first memory die wafer; encapsulating the logic die and the through-mold vias with mold compound; depositing a redistribution layer over a polished surface of the mold compound to couple the redistribution layer to the plurality of through-mold vias and to a plurality of interconnects for the logic die; forming a first plurality of through-silicon vias in the first memory die wafer; forming a first hybrid bonding layer on a back side of the first memory die wafer; and hybrid bonding an active surface of a second memory die wafer to the first hybrid bonding layer to form a wafer-on-wafer hybrid bond between the first memory die wafer and the second memory die wafer.

Finally, in accordance with another aspect of the disclosure, an integrated circuit package is provided that includes: a hybrid bonded stack of memory dies arranged from a bottom-most memory die to a top-most memory die; a redistribution layer; a plurality of through-mold vias coupled between an active surface of the bottom-most memory die and the redistribution layer; and a logic die having an active surface coupled to the redistribution layer through a plurality of interconnects.

These and other advantageous features may be better appreciated through the following detailed description.

### BRIEF DESCRIPTION OF THE DRAWINGS

FIG. 1 illustrates a three-dimensional (3D) integrated circuit package including a logic die and a plurality of memory dies coupled together in accordance with an aspect of the disclosure.

FIG. 2A illustrates an initial stage in the manufacture of the 3D integrated circuit package of FIG. 1 including the deposition of through-mold vias on the active surface of the bottom-most DRAM die in accordance with an aspect of the disclosure.

FIG. 2B illustrates the securing of the back surface of the logic die onto the active surface of the bottom-most DRAM die of FIG. 2A in accordance with an aspect of the disclosure.

FIG. 2C illustrates the encapsulation of the logic die and through-mold vias of FIG. 2B with mold compound followed by a grinding and polishing of the mold compound surface in accordance with an aspect of the disclosure.

FIG. 2D illustrates the deposition of the redistribution layer on the polished mold compound surface of FIG. 2C in accordance with an aspect of the disclosure.

FIG. 2E illustrates the attachment of the redistribution layer of FIG. 2D to a carrier substrate followed by the thinning of the bottom-most DRAM die in accordance with an aspect of the disclosure.

FIG. 2F illustrates the formation of through-silicon vias and deposition of a hybrid bond layer on the back side of the bottom-most DRAM die of FIG. 2D in accordance with an aspect of the disclosure.

FIG. 2G illustrates the attachment and thinning of a second DRAM die onto the hybrid bond layer on the back side of the bottom-most DRAM die of FIG. 2F in accordance with an aspect of the disclosure.

FIG. 2H illustrates the formation of through-silicon vias and deposition of a hybrid bond layer on the back side of the second DRAM die of FIG. 2G in accordance with an aspect of the disclosure.

FIG. 3 is a flowchart for an example method of manufacturing a three-dimensional integrated circuit package including a logic die and a hybrid-bonded stack of memory dies in accordance with an aspect of the disclosure.

FIG. 4 illustrates some example electronic systems including an integrated circuit package in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

In a three-dimensional (3D) integrated circuit package of memory dies, the memory dies are typically stacked using a die-to-wafer (DtW) process and coupled together using a via-first process. The resulting process is costly. To lower costs, a 2.5-dimensional (2.5D) process may be used in which the memory dies couple through a ball grid array to an interposer and from the interposer to the logic die. The bump pitch (required separation between adjacent bumps) limits the bandwidth for the data flow to the memory dies. A three-dimensional (3D) integrated circuit package is disclosed herein that advantageously offers significantly improved bandwidth over 2.5D approaches while offering lower cost as compared to traditional 3D approaches. Some example implementations will now be discussed in more detail.

The logic die in an AI edge device will typically interface with multiple memory dies such as DRAM dies due to the relatively large amount of data needed for AI applications. The following discussion will be directed to the use of DRAM dies in the 3D integrated circuit package to provide this increased memory capacity, but it will be appreciated that other types of random-access memory (RAM) dies such as magnetic RAM may be used in alternative implementations. To maintain a small footprint (package size), the DRAM dies disclosed herein are stacked above the back side of a logic die having its active surface coupled to redistribution layer. Each of the DRAM dies is arranged in the stack to have its active surface facing the redistribution layer. The DRAM dies are arranged in the stack from a bottom-most DRAM die to a top-most DRAM die. Each DRAM die but for the top-most DRAM die includes a plurality of conductive vias (e.g., through-silicon vias) that extend from the active surface of the DRAM die to the back surface of the DRAM die. In addition, a hybrid bonding layer covers the back surface of each of the DRAM dies but for the top-most DRAM die. In this fashion, a successive DRAM die in the stack has its active surface hybrid bonded to the back surface of a preceding DRAM in the stack through the corresponding hybrid bond layer. The active surface of the lower-most DRAM die in the stack couples through through-mold vias to the redistribution layer. The active surface of the logic die couples to the redistribution layer through a plurality of interconnects such as metal pillars (e.g., copper pillars) or micro bumps.

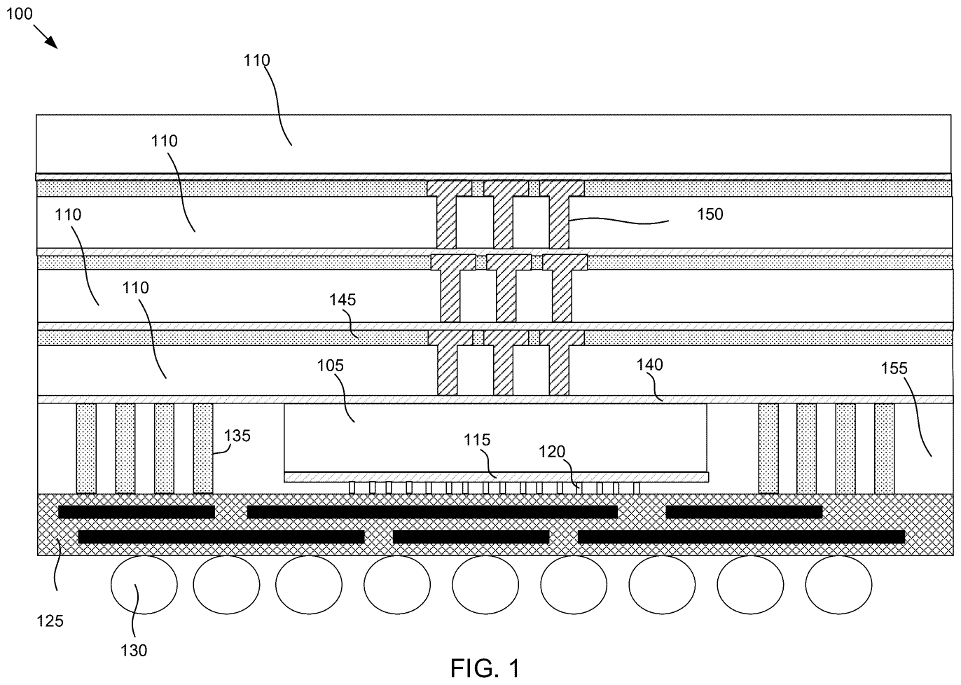

An example 3D integrated circuit package 100 including a hybrid-bonded stack of DRAM dies 110 shown in FIG. 1. Each DRAM die 110 is arranged in the stack to have its active surface 140 including both a front-end-of-line layer (not illustrated) and a back-end-of-line layer (not illustrated) facing a redistribution layer 125. A logic die 105 also has its active surface 115 facing the redistribution layer 125. A plurality of interconnects such as a plurality of metal pillars 120 couple between conductive pads (not illustrated) on the active surface 115 and corresponding conductive pads (also not illustrated) on the redistribution layer 125. Alternatively, the plurality of interconnects may be formed using a plurality of micro bumps such as copper or copper/tin micro bumps. A mold compound 155 such as epoxy encapsulates the through-mold vias 135 and the logic die 105.

The redistribution layer 125 may be formed using a suitable dielectric polymer such as polyimide that is photolithographically patterned in either a positive or negative fashion. A conductive metal such as copper or titanium/copper may then be sputtered or electroplated onto the patterned dielectric polymer to form the desired electrical connections in the redistribution layer 125. The metal and dielectric polymer may be layered so that multiple patterned metallic layers are present in the redistribution layer 125.

A bottom-most DRAM die 110 in the package 100 has conductive pads (not illustrated) on its active surface 140 coupled to through-mold vias 135 to corresponding conductive pads (not illustrated) on the redistribution layer 125. This bottom-most DRAM die 110 also includes a plurality of through-silicon vias 150 that couple from the active surface 140 of the bottom-most DRAM die 110 to a hybrid bonding layer 145 on its back side. The hybrid bonding layer 145 of the bottom-most DRAM die 110 hybrid bonds to an active surface 140 of a second-to-bottom-most DRAM die 110 in the stacking order. As defined herein, a hybrid bond combines both a dielectric bond (e.g., a silicon dioxide bond) and an embedded metal bond (e.g. a copper bond).

Each DRAM die 110 in the stack but for a top-most DRAM die 110 in the stack includes a hybrid bonding layer 145 on its back surface that hybrid bonds to an active surface 140 of a successive one of the DRAM dies in the stack. Each hybrid bonding layer 145 is thus patterned with metal leads that fan out from the die's through-silicon vias 150 to respective conductive pads (not illustrated) in the hybrid bonding layer 145. The active surface 140 of the successive DRAM die 110 in the stack includes conductive pads (not illustrated) that are arranged identically with the conductive pads in the corresponding hybrid bonding layer 145. As will be explained further herein, the resulting hybrid bonding may be performed in a wafer-on-wafer (WoW) process such that one wafer has its active surface hybrid bonding to the hybrid bonding layer on an underlying wafer. This hybrid bonding may occur through heating.

A read of data from a DRAM die 110 other than the bottom-most DRAM die 110 in the stack will thus flow through its active surface 140 and through the hybrid bonding layer 145 of the preceding DRAM die 110 in the stack to the preceding DRAM die's through-silicon vias 150. The data may then continue to flow in this fashion from DRAM die 110 to DRAM die 110 in the stack to active surface 140 of the bottom-most DRAM die 110 in the stack. The data may then flow from the active surface 140 of the bottom-most DRAM die 110 to the through-mold vias 135, then through the redistribution layer 135, and then through the metal pillars 120 to finally be received by the active surface 115 of the logic die 105. A write of data may follow the reverse order. Signaling between external circuits and the 3D integrated circuit package 100 (as well as the provision of ground and power) may occur through bumps or micro bumps 130 such as arranged in a ball grid array on a bottom surface of the redistribution layer 125.

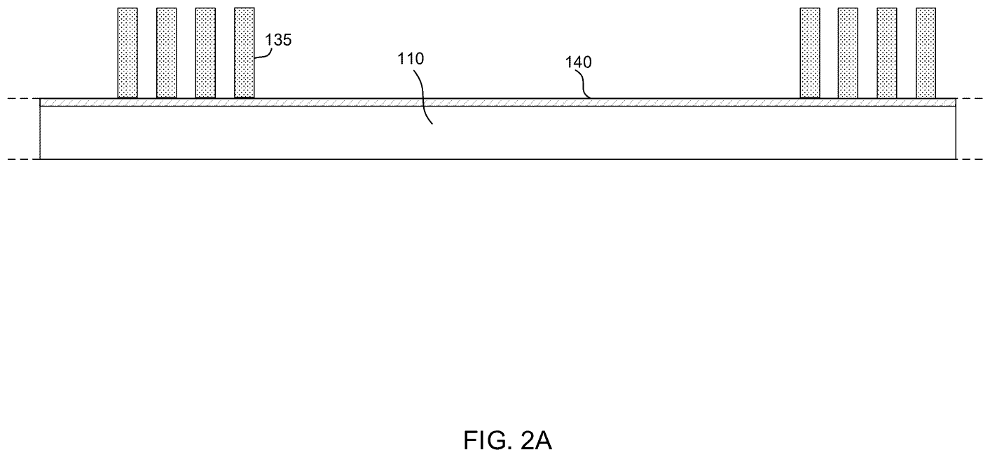

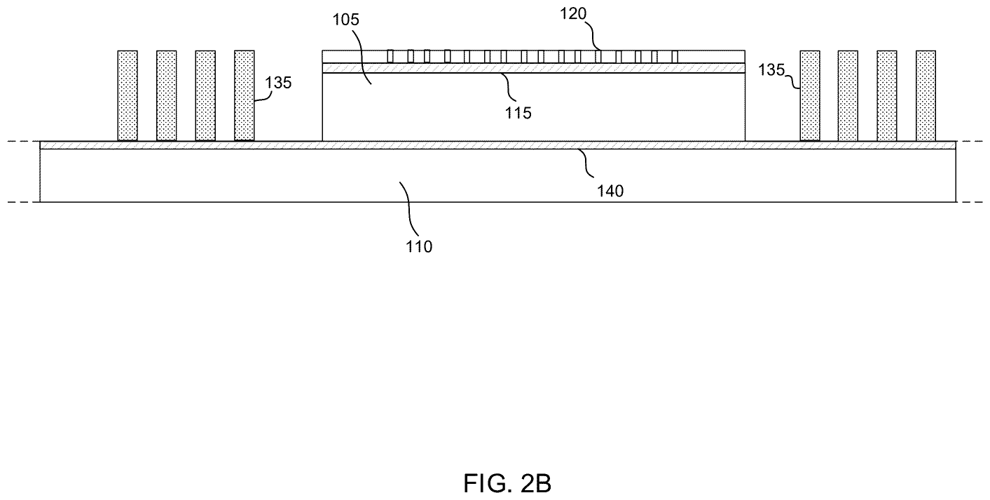

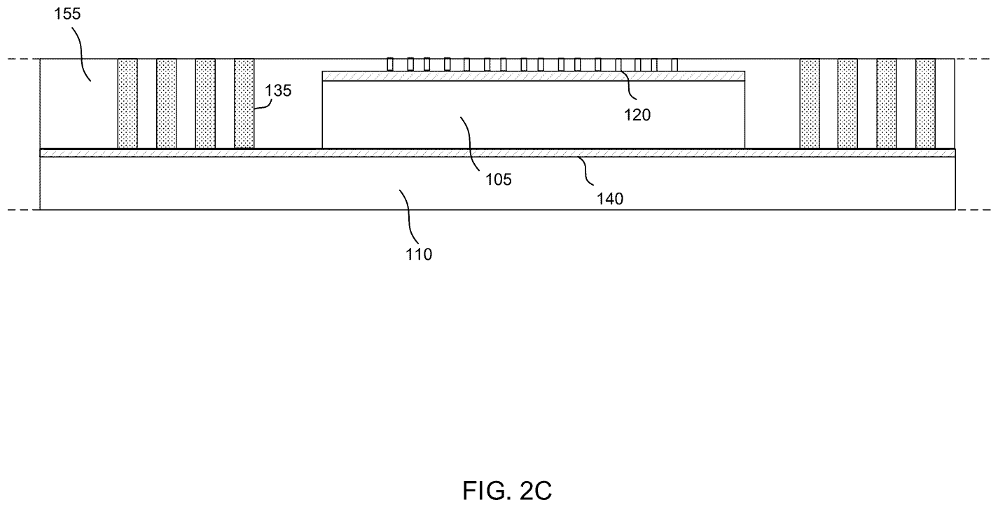

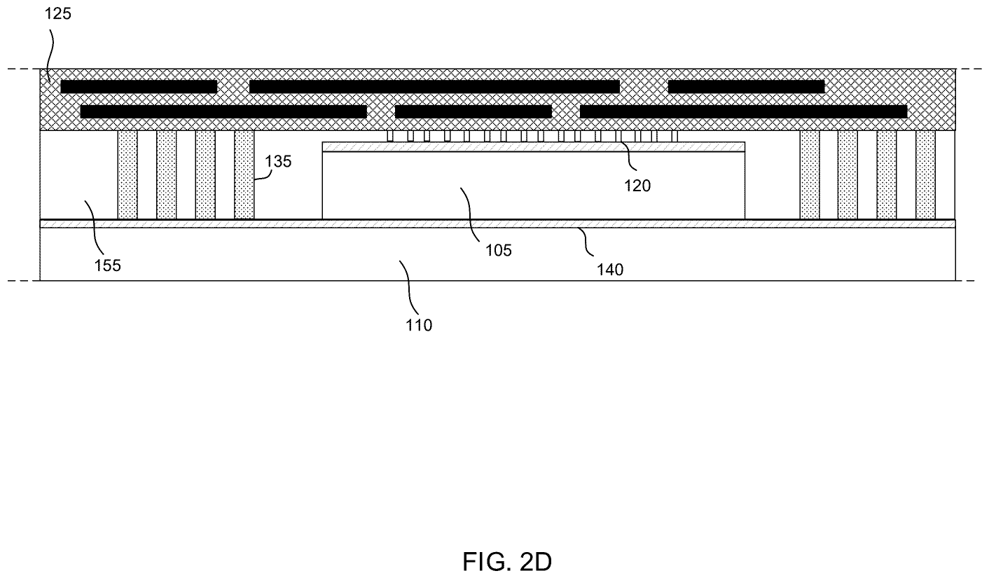

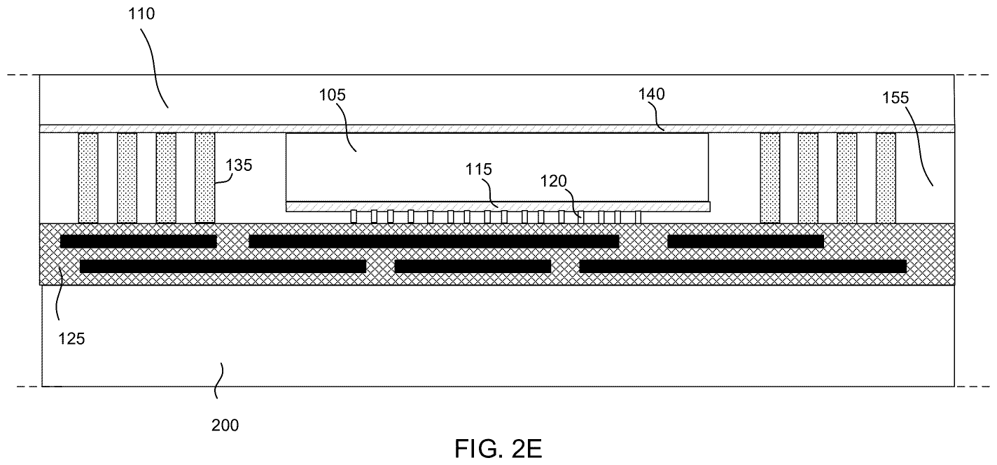

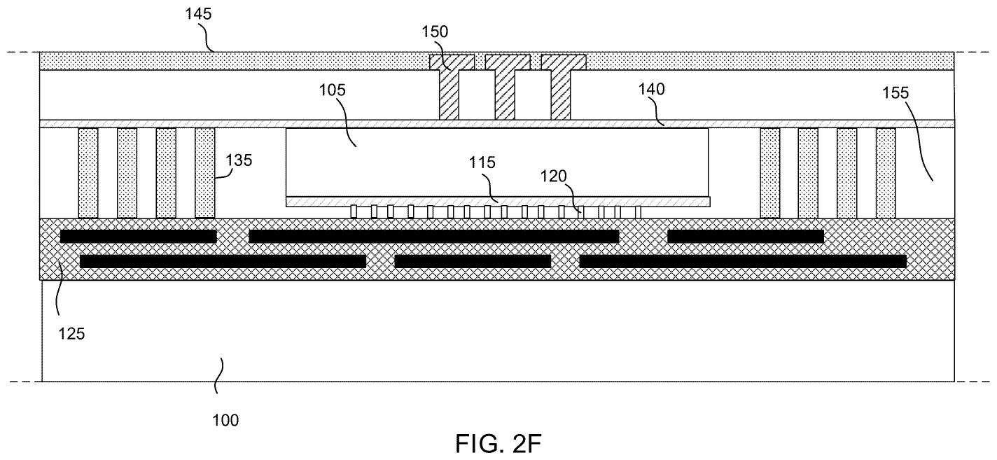

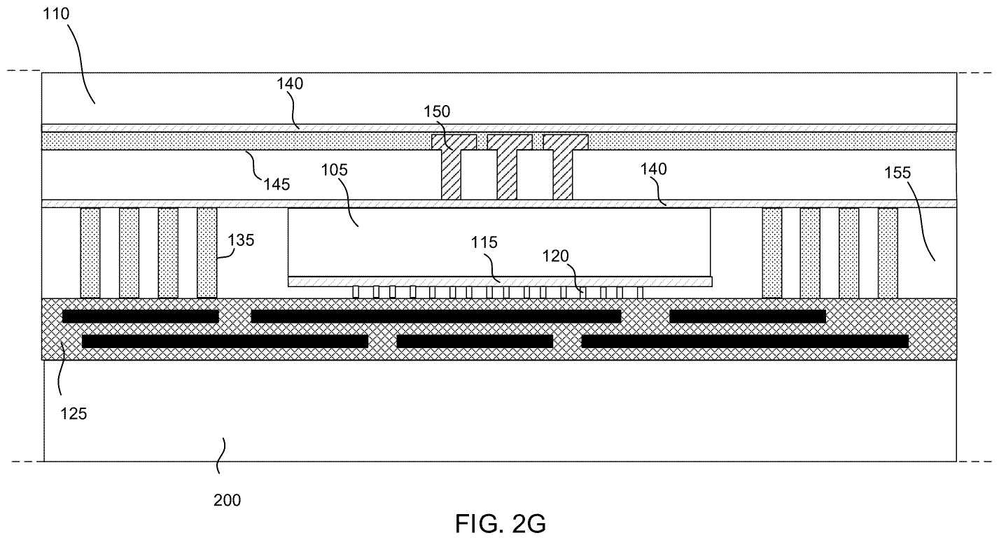

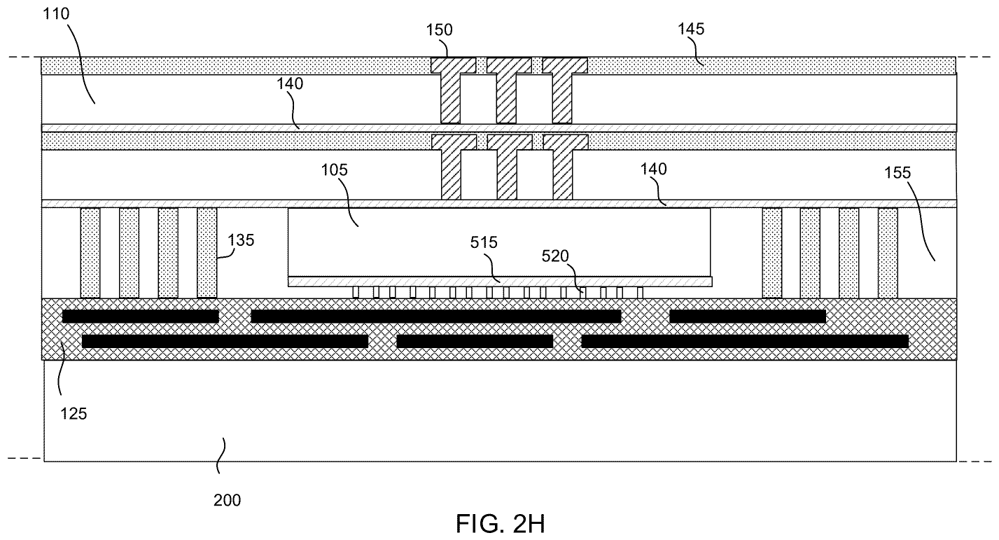

A fabrication process for the 3D integrated circuit package 100 will now be discussed. The process begins with the fabrication of the through-mold vias 135 on the active surface 140 of a wafer including the bottom-most DRAM die 110 as shown in FIG. 2A. Since the bottom-most DRAM die 110 has not yet been singulated from its wafer, the wafer is only partially shown in FIG. 2A using dotted lines for illustration clarity. To form the through-mold vias 135, a seed layer of a suitable metal such as copper is deposited over the active surface 140 followed by the deposition of a photoresist layer (not illustrated). The photoresist layer may then be patterned to form vias in the photoresist layer at the desired locations for the through-mold vias 135, followed by an electroplating or vapor deposition of a suitable metal such as copper in the vias. The photoresist is then removed followed by a light etching to remove any remaining exposed seed layer to complete the formation of the through-mold vias 135.

As shown in FIG. 2B, a back surface of the logic die 105 is then secured to the active surface 140. Since the bottom-most DRAM die 110 has not yet been singulated from its wafer (the wafer again being shown partially using dotted lines for illustration clarity), the bonding of the back side of the logic die 105 to the active surface 140 is a die-to-wafer bonding. Prior to this bonding, the DRAM die 110 may be patterned with metal pillars 120 (e.g., copper pillars) on its active surface 115. The metal pillars 120 may be plated or deposited in corresponding vias in mold compound. In alternative implementations, the interconnects for the logic die 105 may be formed using micro bumps.

As shown in FIG. 2C, the through-mold vias 135 and logic die 105 may then be encapsulated in mold compound 155 such as epoxy. The upper surface of the mold compound 155 is then ground and polished to form a polished surface for the deposition of the redistribution layer 125 as illustrated in FIG. 2D. This deposition is a wafer level deposition as the bottom-most DRAM die 110 has not yet been singulated from its wafer (partially illustrated using dotted lines). As shown in FIG. 2E, a bottom surface of the redistribution layer 125 is bonded to a carrier substrate 200 (in this wafer-on-wafer process, a wafer-sized carrier substrate 200 such as a silicon wafer) so that a back side of wafer including the bottom-most DRAM die 110 may be thinned. With the wafer thinned that includes the bottom-most DRAM die 110, vias are formed in the wafer for the deposition of through-silicon vias 150 and the hybrid bonding layer 145 as shown in FIG. 2F. The through-silicon vias 150 may be formed using any suitable conductive material such as copper, tungsten, or polysilicon.

As shown in FIG. 2G, a wafer (partially illustrated using dotted lines) including what will become the second-most bottom DRAM die 110 may then have its active surface 140 hybrid bonded to the hybrid bonding layer 145 for the wafer including the bottom-most DRAM die 110. The wafer including what will become the second-most bottom DRAM die 110 may then be thinned and patterned with through-silicon vias 150 and a hybrid bonding layer 145 as shown in FIG. 2H. In this fashion, additional DRAM wafers may be hybrid bonded to the stack, thinned, and patterned with through-silicon vias 150 and hybrid bonding layers 145 until the wafer for the top-most DRAM die 110 is reached. This wafer is hybrid bonded but is not patterned with through-silicon vias 150 as they are not necessary for the top-most DRAM die 110. The wafer for the carrier substrate 200 is then removed and the 3D integrated circuit package 100 singulated from the stacked wafers to complete its manufacture.

It may thus be appreciated that the through-silicon vias 150 in each of the DRAM dies 110 but for the top-most DRAM die 110 are formed using a via-last process. As implied by the name via-last, a via-last process forms the through-silicon vias 150 after the front-end-of-line and back-end-of-line processing of the corresponding wafers is already completed. The resulting wafer-on-wafer and via-last through-silicon via processing to manufacture the 3D integrated circuit package 100 is advantageously cost-effective as compared to more expensive die-to-wafer approaches in stacking the DRAMs. In addition, the 3D integrated circuit package 100 has an advantageous increase in bandwidth for the data flow between its logic die 105 and DRAM dies 110 as compared to the bandwidth-reducing effect of the ball grid array coupling for the same data flow in a traditional 2.5D integrated circuit package.

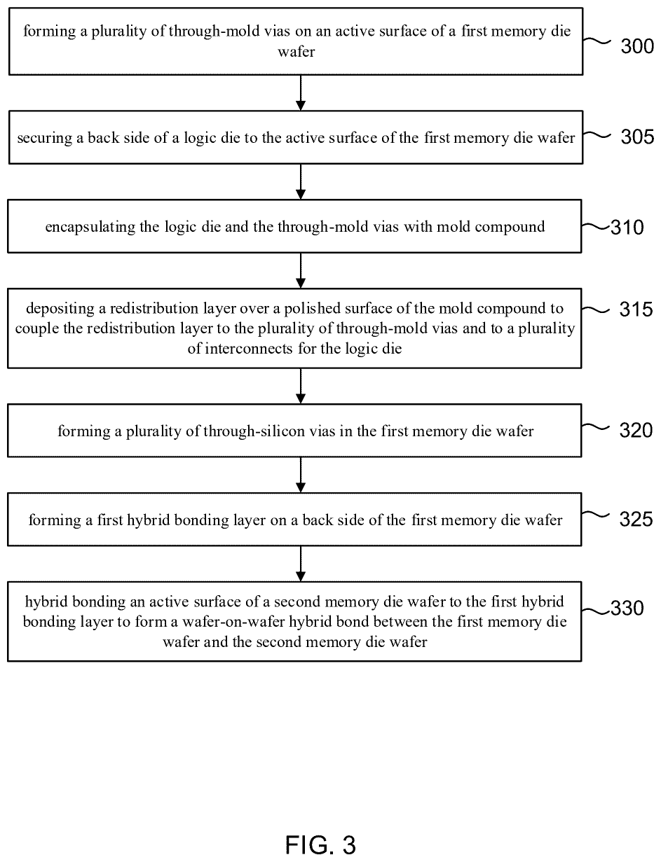

A method for the 3D integrated circuit package manufacture will now be summarized with respect to the flowchart of FIG. 3. The method includes an act 300 of forming a plurality of through-mold vias on an active surface of a first memory die wafer. The deposition of the through-mold vias 135 as discussed with regard to FIG. 2A is an example of act 300. The method further includes an act 305 of securing a back side of a logic die to the active surface of the first memory die wafer. The bonding of the logic die 105 as discussed with respect to FIG. 2B is an example of act 305. The method further includes an act 310 of encapsulating the logic die and the through-mold vias with mold compound. The encapsulation with mold compound 155 as discussed with respect to FIG. 2C is an example of act 310. In addition, the method includes an act 315 of depositing a redistribution layer over a polished surface of the mold compound to couple the redistribution layer to the plurality of through-mold vias and to a plurality of interconnects for the logic die. The deposition of the redistribution layer 125 as discussed with respect to FIG. 2D is an example of act 315. The method also includes an act 320 of forming a plurality of through-silicon vias in the first memory die wafer. The formation of the through-silicon vias 150 as discussed with respect to FIG. 2F is an example of act 320. The method further includes an act 325 of forming a first hybrid bonding layer on a back side of the first memory die wafer. The formation of the hybrid bonding layer 145 as discussed with respect to FIG. 2F is an example of act 325. Finally, the method includes an act 330 of hybrid bonding an active surface of a second memory die wafer to the first hybrid bonding layer to form a wafer-on-wafer hybrid bond between the first memory die wafer and the second memory die wafer. The hybrid bonding as discussed with respect to FIG. 2H is an example of act 330.

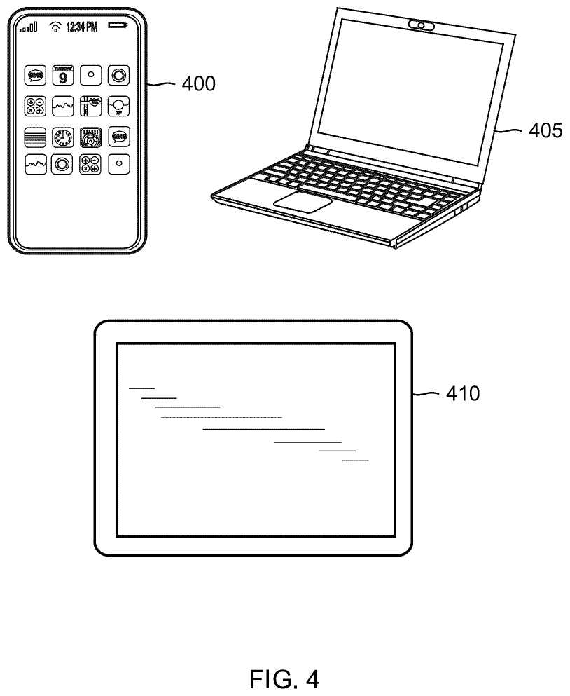

An integrated circuit package including a logic die and a plurality of memory dies as disclosed herein may be incorporated in a wide variety of electronic systems. For example, as shown in FIG. 4, a cellular telephone 400, a laptop computer 405, and a tablet 410 may all include an integrated circuit package in accordance with the disclosure. Other exemplary edge-AI-enabled electronic systems such as automotive sensors, video doorbells, and so on may also be configured with an integrated circuit package constructed in accordance with the disclosure.

Some example implementations are described by the following numbered clauses:

Clause 1. An integrated circuit package comprising:
a redistribution layer;
a logic die including an active surface coupled to the redistribution layer through a plurality of interconnects;
a stack of memory dies stacked from a bottom-most memory die to a top-most memory die, each memory die including an active surface facing the redistribution layer, wherein the active surface of the bottom-most memory die abuts a back side of the logic die, and wherein each memory die, but for the top-most memory die in the stack, includes a plurality of conductive vias extending from the active surface of the memory die to a back side of the memory die; and
a plurality of through-mold vias coupled between the active surface of the bottom-most memory die and the redistribution layer.

Clause 2. The integrated circuit package of clause 1, wherein the plurality of interconnects comprises a plurality of metal pillars.

Clause 3. The integrated circuit package of clause 1, wherein the plurality of interconnects comprises a plurality of micro bumps.

Clause 4. The integrated circuit package of any of clauses 1-3, wherein the active surface of each memory die but for the bottom-most memory die is hybrid bonded to the back side of a preceding memory die in the stack.

Clause 5. The integrated circuit package of any of clauses 1-4, wherein each memory die comprises a dynamic random-access memory (DRAM) die.

Clause 6. The integrated circuit package of clause 5, wherein each dynamic random-access memory die comprises silicon, and wherein the plurality of conductive vias in each of the dynamic random-access memory dies, but for a top-most dynamic random-access memory die in the stack, comprises a plurality of through-silicon vias.

Clause 7. The integrated circuit package of clause 6, wherein each plurality of through-silicon vias comprises a plurality of polysilicon through-silicon vias.

Clause 8. The integrated circuit package of claim 6, wherein each plurality of through-silicon vias comprises a plurality of copper through-silicon vias.

Clause 9. The integrated circuit package of any of clauses 1-8, wherein the logic die, the plurality of interconnects, and the plurality of through-mold vias are encapsulated in a mold compound.

Clause 10. The integrated circuit package of any of clauses 1-9, wherein the integrated circuit package is incorporated into a cellular telephone.

Clause 11. A method of manufacturing an integrated circuit package, comprising:
forming a plurality of through-mold vias on an active surface of a first memory die wafer;
securing a back side of a logic die to the active surface of the first memory die wafer;
encapsulating the logic die and the through-mold vias with mold compound;
depositing a redistribution layer over a polished surface of the mold compound to couple the redistribution layer to the plurality of through-mold vias and to a plurality of interconnects for the logic die;
forming a first plurality of through-silicon vias in the first memory die wafer;
forming a first hybrid bonding layer on a back side of the first memory die wafer; and
hybrid bonding an active surface of a second memory die wafer to the first hybrid bonding layer to form a wafer-on-wafer hybrid bond between the first memory die wafer and the second memory die wafer.

Clause 12. The method of clause 11, further comprising:
forming a second plurality of through-silicon vias in the second memory die wafer.

Clause 13. The method of clause 12, further comprising:
singulating the first memory die wafer and the second memory die wafer.

Clause 14. The method of clause 11, further comprising:
depositing a plurality of metal pillars on an active surface of the logic die to form the plurality of interconnects.

Clause 15. An integrated circuit package, comprising:
a hybrid bonded stack of memory dies arranged from a bottom-most memory die to a top-most memory die;
a redistribution layer;
a plurality of through-mold vias coupled between an active surface of the bottom-most memory die and the redistribution layer; and
a logic die having an active surface coupled to the redistribution layer through a plurality of interconnects.

Clause 16. The integrated circuit package of clause 15, wherein the plurality of interconnects comprises a plurality of metal pillars.

Clause 17. The integrated circuit package of clause 15, wherein the plurality of interconnects comprises a plurality of micro bumps.

Clause 18. The integrated circuit package of any of clauses 15-17, wherein each memory die, but for the top-most memory die in the stack, includes a plurality of through-silicon vias.

Clause 19. The integrated circuit package of clause 18, wherein each plurality of through-silicon vias comprises a plurality of copper through-silicon vias.

Clause 20. The integrated circuit package of clause 18, wherein each plurality of through-silicon vias comprises a plurality of polysilicon through-silicon vias.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. An integrated circuit package comprising:
a redistribution layer;
a logic die including an active surface coupled to the redistribution layer through a plurality of interconnects;
a stack of memory dies stacked from a bottom-most memory die to a top-most memory die, each memory die including an active surface facing the redistribution layer, wherein the active surface of the bottom-most memory die abuts a back side of the logic die, and wherein each memory die, but for the top-most memory die in the stack, includes a plurality of conductive vias extending from the active surface of the memory die to a back side of the memory die; and
a plurality of through-mold vias coupled between the active surface of the bottom-most memory die and the redistribution layer.

2. The integrated circuit package of claim 1, wherein the plurality of interconnects comprises a plurality of metal pillars.

3. The integrated circuit package of claim 1, wherein the plurality of interconnects comprises a plurality of micro bumps.

4. The integrated circuit package of claim 1, wherein the active surface of each memory die, but for the bottom-most memory die in the stack, is hybrid bonded to the back side of a preceding memory die in the stack.

5. The integrated circuit package of claim 4, wherein each memory die comprises a dynamic random-access memory (DRAM) die.

6. The integrated circuit package of claim 5, wherein each dynamic random-access memory die comprises silicon, and wherein the plurality of conductive vias in each of the dynamic random-access memory dies, but for a top-most dynamic random-access memory die in the stack, comprises a plurality of through-silicon vias.

7. The integrated circuit package of claim 6, wherein each plurality of through-silicon vias comprises a plurality of polysilicon through-silicon vias.

8. The integrated circuit package of claim 6, wherein each plurality of through-silicon vias comprises a plurality of copper through-silicon vias.

9. The integrated circuit package of claim 1, wherein the logic die, the plurality of interconnects, and the plurality of through-mold vias are encapsulated in a mold compound.

10. The integrated circuit package of claim 1, wherein the integrated circuit package is incorporated into a cellular telephone.

11. A method of manufacturing an integrated circuit package, comprising:
forming a plurality of through-mold vias on an active surface of a first memory die wafer;
securing a back side of a logic die to the active surface of the first memory die wafer;
encapsulating the logic die and the through-mold vias with mold compound;
depositing a redistribution layer over a polished surface of the mold compound to couple the redistribution layer to the plurality of through-mold vias and to a plurality of interconnects for the logic die;
forming a first plurality of through-silicon vias in the first memory die wafer;
forming a first hybrid bonding layer on a back side of the first memory die wafer; and
hybrid bonding an active surface of a second memory die wafer to the first hybrid bonding layer to form a wafer-on-wafer hybrid bond between the first memory die wafer and the second memory die wafer.

12. The method of claim 11, further comprising:
forming a second plurality of through-silicon vias in the second memory die wafer.

13. The method of claim 12, further comprising:
singulating the first memory die wafer and the second memory die wafer.

14. The method of claim 11, further comprising:
depositing a plurality of metal pillars on an active surface of the logic die to form the plurality of interconnects.

15. An integrated circuit package, comprising:
a hybrid bonded stack of memory dies arranged from a bottom-most memory die to a top-most memory die;
a redistribution layer;
a plurality of through-mold vias coupled between an active surface of the bottom-most memory die and the redistribution layer; and
a logic die having an active surface coupled to the redistribution layer through a plurality of interconnects.

16. The integrated circuit package of claim 15, wherein the plurality of interconnects comprises a plurality of metal pillars.

17. The integrated circuit package of claim 15, wherein the plurality of interconnects comprises a plurality of micro bumps.

18. The integrated circuit package of claim 15, wherein each memory die, but for the top-most memory die in the stack, includes a plurality of through-silicon vias.

19. The integrated circuit package of claim 18, wherein each plurality of through-silicon vias comprises a plurality of copper through-silicon vias.

20. The integrated circuit package of claim 18, wherein each plurality of through-silicon vias comprises a plurality of polysilicon through-silicon vias.
